(19) United States
(12) Patent Application Publication
(10) Pub. No.: US 2024/0061649 A1
(43) Pub. Date: Feb. 22, 2024

(54) IN-MEMORY COMPUTING (IMC) PROCESSOR AND OPERATING METHOD OF IMC PROCESSOR

(71) Applicant: SAMSUNG ELECTRONICS CO., LTD., Suwon-si (KR)

(72) Inventors: Soon-Wan KWON, Suwon-si (KR); Seok Ju YUN, Suwon-si (KR); Seungchul JUNG, Suwon-si (KR)

(73) Assignee: SAMSUNG ELECTRONICS CO., LTD., Suwon-si (KR)

(21) Appl. No.: 18/306,686

(22) Filed: Apr. 25, 2023

(30) Foreign Application Priority Data
Aug. 19, 2022 (KR) 10-2022-0103946

(51) Int. Cl. G06F 7/544; G06F 7/527; G11C 7/10

(52) U.S. Cl. CPC G06F 7/5443; G06F 7/5277; G11C 7/1069

(57) ABSTRACT

An in-memory computing (IMC) processor includes IMC macros, and includes a static random access memory (SRAM) IMC device including the plurality of IMC macros, and configured to perform a multiply and accumulate (MAC) operation between input data and first weight data of a first weight map applied to a first of IMC macros in a first direction in which an input feature map including the input data is written to the first IMC macro, and a two-dimensional (2D) shift accumulator configured to perform a shift operation on partial sums corresponding to respective MAC operation results of the IMC macros and accumulate a result of the shift operation.

### CROSS-REFERENCE TO RELATED APPLICATIONS

This application claims the benefit under 35 USC § 119(a) of Korean Patent Application No. 10-2022-0103946, filed on Aug. 19, 2022, in the Korean Intellectual Property Office, the entire disclosure of which is incorporated herein by reference for all purposes.

### BACKGROUND

### 1. Field

The following disclosure relates to an in-memory computing (IMC) processor and an operating method of the IMC processor.

### 2. Description of Related Art

The utilization of deep neural networks (DNNs) is leading to industrial advancement based on artificial intelligence (AI). One type of DNN, a convolutional neural network (CNN), is widely used in various application fields such as image and signal processing, object recognition, computer vision, and the like. A CNN may be configured to perform a multiple and accumulate (MAC) operation that repeats multiplication and addition using a considerably large number of potentially large matrices. When an application of a CNN is executed using general-purpose processors, an operation such as a MAC operation may, although not complex, may require a considerable amount of computation. A MAC operation, which may be used in applications other than CNN applications, calculates an inner product of two vectors and accumulates and sums the values. Such an operation may be performed through in-memory computing.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an in-memory computing (IMC) processor includes IMC macros, a static random access memory (SRAM) IMC device including the IMC macros, and configured to perform a multiply and accumulate (MAC) operation between input data and first weight data of a first weight map applied to a first of the IMC macros in a first direction in which an input feature map including the input data is written to the first IMC macro, and a two-dimensional (2D) shift accumulator configured to perform a shift operation on partial sums corresponding to respective MAC operation results of the IMC macros and accumulate a result of the shift operation.

An output end of the first IMC macro may be connected to an input end of a second of the IMC macros, and the SRAM IMC device may be configured to write data of an output feature map of the first IMC macro to a second memory array of the second IMC macro in the first direction as the input data in parallel, and perform, in response to second weight data of a second weight map being applied to the second IMC macro, a MAC operation between the data written to the second memory array and the second weight data in the first direction.

The IMC macros may be configured to share the 2D shift accumulator.

The 2D shift accumulator may include a buffer, the buffer may include a first region for storing or accumulating a MAC operation result corresponding to the first IMC macro, and a second region for preventing data loss due to the shift operation, and the size of the first region and the size of the second region may be determined based on a size of the first IMC macro.

The 2D shift accumulator may be configured to perform an accumulate operation on the partial sums by performing the shift operation on the respective MAC operation results of the IMC macros in at least one direction of up, down, left, and right directions.

The input feature map may include 2D input data corresponding to word lines and bit lines of a first memory array included in the first IMC macro.

The MAC operation may include a linear operation or a convolution operation.

The IMC processor may further include an input streamer configured to delay applying a weight map corresponding to each of the IMC macros by a unit cycle and to apply the delayed weight map to the corresponding IMC macro.

The input streamer may be configured to read, from memory devices, weight data of weight maps corresponding to one or more IMC macros that are operable at the same time among the plurality of IMC macros, and apply the read weight data to the corresponding IMC macro at a point in time delayed by the unit cycle, for each of the one or more IMC macros.

Each of the IMC macros may include a memory array including bit cells, wherein bit cells connected to the same bit lines may be configured to receive the same 1-bit weight data, and each of the plurality of bit cells may be configured to perform an AND operation between input data stored in the corresponding bit cell and weight data of a weight map corresponding to each of the plurality of IMC macros, and a digital operator configured to accumulate a result of the AND operations of respective bit cells.

The digital operator may include an adder configured to perform an add operation on the result of the AND operation, and a shift accumulator configured to sequentially accumulate a result of the add operation through a shift operation.

The memory array may include word lines, bit lines intersecting with the word lines, and the bit cells disposed at intersecting points between the plurality of word lines and the plurality of bit lines, wherein each of the bit cells may be configured to store the input data.

The IMC processor may be integrated into at least one device selected from the group consisting of a mobile device, a mobile computing device, a mobile phone, a smart phone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, and a medical device.

In another general aspect, a SRAM IMC macro device includes IMC macros, wherein the SRAM IMC macro device is configured to perform a multiply and accumulate (MAC) operation between input data and first weight data of a first weight map applied to a first of the IMC macros in a first direction in which an input feature map including the input data is written to the first IMC macro.

An output end of the first IMC macro among the plurality of IMC macros may be connected to an input of a second of the IMC macros, and the SRAM IMC device may be further configured to write data, of an output feature map of the first IMC macro, to a second memory array of the second IMC macro, in the first direction as the input data in parallel, and perform, in response to second weight data of a second weight map being applied to the second IMC macro, a MAC operation between the data written to the second memory array and the second weight data in the first direction.

In another general aspect, an operating method of an IMC processor includes IMC macros, and the method includes writing input data of an input feature map to a first of the IMC macros in a first direction, performing a multiply and accumulate (MAC) operation between the input data and weight data of a weight map corresponding to the first IMC macro by reading the weight data and applying the weight data to the first IMC macro in the first direction, accumulating a result of the MAC operation in a two-dimensional (2D) shift accumulator, and outputting a result of the accumulating according to whether the weight data is last data of the weight map.

The performing of the MAC operation may include delaying applying a weight map corresponding to each of the plurality of IMC macros by a unit cycle and applying the delayed weight map to the corresponding IMC macro.

The applying to the corresponding IMC macro may include reading weights corresponding to one or more IMC macros that are operable at the same time among the IMC macros, and applying the read weight data to a memory array of the corresponding IMC macro in the first direction at a point in time delayed by the unit cycle, for each of the one or more IMC macros.

The performing of the MAC operation may include iteratively reading the weight data and applying the read weight data to a memory array of the first IMC macro in the first direction until a last bit of a column channel of the weight map stored in a memory device is reached.

The outputting of the result of the accumulating may include reading next weight data of the weight data from the weight map and applying the next weight data to the first IMC macro, in response to the weight data not being the last data of the weight map, and shifting the result of the operation in the 2D shift accumulator.

Other features and aspects will be apparent from the following detailed description, the drawings, and the claims.

### BRIEF DESCRIPTION OF THE DRAWINGS

FIG. 1 illustrates an example of a relationship between an in-memory computing (IMC) macro and an operation performed by a neural network, according to one or more embodiments.

FIG. 2A illustrates an example of a data flow when a convolution operation is performed by an IMC processor, according to one or more embodiments.

FIG. 2B illustrates an example of reusing input data in a convolution operation, according to one or more embodiments.

FIG. 3 illustrates an example of using an output of a previous IMC macro for a next IMC macro as it is, in an in-memory computing macro having a general structure, according to one or more embodiments.

FIG. 4 illustrates an example of a hardware structure of an IMC processor, according to one or more embodiments.

FIG. 5 illustrates an example structure of an IMC macro of a static random-access memory (SRAM) IMC device, according to one or more embodiments.

FIG. 6 illustrates an example structure and an operation of a two-dimensional (2D) shift accumulator, according to one or more embodiments.

FIG. 7 illustrates an example of an operation of an input streamer, according to one or more embodiments.

FIG. 8 illustrates an example of storing input data in an IMC macro, according to one or more embodiments.

FIG. 9 illustrates an example of performing a convolution operation in an IMC processor, according to one or more embodiments.

FIG. 10 illustrates an example of an electronic system including an IMC processor, according to one or more embodiments.

FIG. 11 illustrates an examples of an operating method of an IMC processor, according to one or more embodiments.

FIG. 12 illustrates another example of an operating method of an IMC processor, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

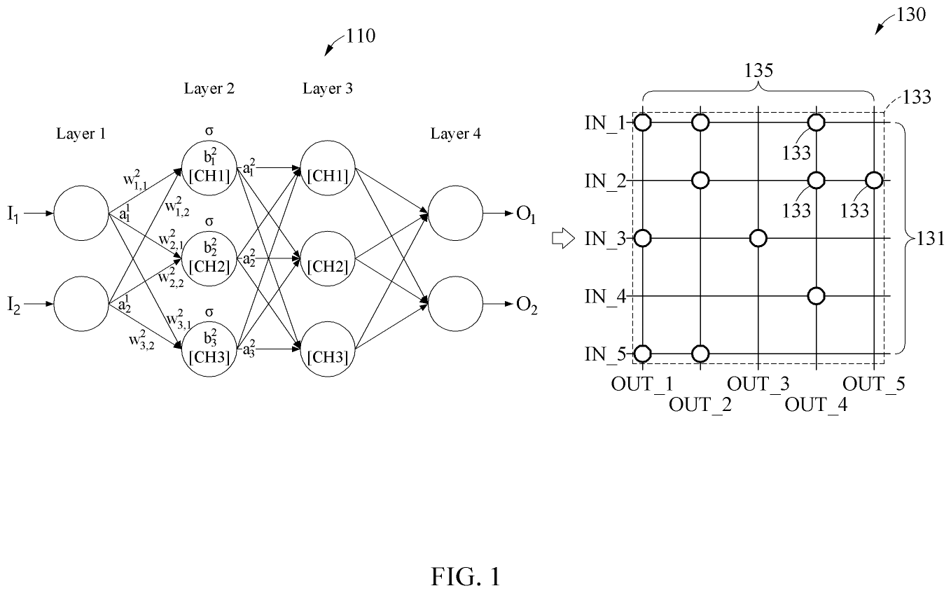

FIG. 1 illustrates an example of a relationship between an in-memory computing (IMC) macro and an operation performed by a neural network, according to one or more embodiments. Referring to FIG. 1, a neural network 110 and a memory array 130 of an IMC macro corresponding to the neural network 110 are shown.

IMC is a computing architecture that causes an operation to be performed directly in a memory in which data is stored (without having to move the data into or out of the memory), to overcome the limited performance and power due to frequent data movement between the memory and an operation unit (e.g., a processor), occurring in the von Neumann architecture. Usually, data subject to IMC computation may be operated on in-place (e.g., subjected to a MAC operation), that is, where the data is being stored by the IMC memory device. IMC may be generally divided into analog IMC and digital IMC according to the domain in which an operation is to be performed. Analog IMC may perform an operation in an analog domain, such as, for example, current, charge, time, or the like. Digital IMC may perform an operation in a digital domain using a logic circuit. Some IMC architectures may use a blend of analog and digital IMC.

IMC may accelerate a matrix operation and/or a multiply and accumulate (MAC) operation that performs, all at once, an addition of a number of multiplications for learning-inference of artificial intelligence (AI). In this case, an operation of multiplication and summation for the neural network 110 may be performed through the memory array 130 including bit cells in an IMC macro.

The IMC macro may perform the operation of multiplication and summation by computing functions of the memory array 130 including the bit cells and operators added to the memory array 130, thereby enabling machine learning/inferencing of the neural network 110.

For example, the neural network 110 may be a deep neural network (DNN) including an input layer (Layer 1), two hidden layers (Layer 2 and Layer 3), and an output layer (Layer 4). However, examples are not limited thereto. The neural network 110 may perform an operation based on received input data (e.g., I₁ and I₂) and generate output data (e.g., O₁ and O₂) based on a result of performing the operation.

The neural network 110 may be a DNN or an n-layer neural network including two or more hidden layers, as described above. When the neural network 110 is implemented with a DNN architecture, the neural network 110 includes many layers capable of processing valid information. Thus, the neural network 110 may process more complex data sets than a neural network having one or several layers. Meanwhile, although FIG. 1 illustrates a neural network 110 including four layers, examples are not limited thereto. The neural network 110 may include fewer or more layers, or may include fewer or more channels. The neural network 110 may include layers in various architectures different from that shown in FIG. 1.

Each of the layers included in the neural network 110 may channels. The channel(s) may correspond to a plurality of nodes, processing elements (PEs), units, or other similar terms.

The channels included in each of the layers of the neural network 110 may be connected to each other to process data. For example, one channel may perform an operation by receiving data from other channels, and output an operation result to other channels.

An input and an output of each of the channels may be referred to as an input activation and an output activation, respectively. An “activation” may be a parameter corresponding to an output of one channel and an input for channels included in a subsequent layer, at the same time. Meanwhile, each of the channels may determine its activation based on weights and based on activations received from channels included in a previous layer. A weight is a parameter used to calculate an output activation in each channel, and may be a value assigned to a connection relationship between channels.

Each of the channels may be processed by a computational unit (CU) or processing element (PE) that receives an input and outputs an output activation, and the input and the output of each of the channels may be mapped.

For example, a denotes an activation function. wⱼₖⁱ denotes a weight from a k-th channel included in an (i−1)-th layer to a j-th channel included in an i-th layer. bⱼⁱ denotes a bias of the j-th channel included in the i-th layer.

When aⱼⁱ denotes an activation of the j-th channel of the i-th layer, the activation aⱼⁱ may be calculated using Equation 1.

$${a}_{j}^{i} = σ ( {\sum }_{k} ( {w}_{jk}^{i} \times {a}_{k}^{i - 1} ) + {b}_{j}^{i} ) \qquad Equation 1$$

As shown in FIG. 1, an activation of a first channel (CH 1) of the second layer (Layer 2) may be expressed as a₁². Also, a₁² may have a value of a₁²=σ(w_{1,1}²×a₁¹+w_{1,2}²×a₂¹+b₁²) according to Equation 1. The activation function a may be, for example, any one of rectified linear unit (ReLU), sigmoid, hyperbolic tangent (tan h), or Maxout. However, examples are not limited thereto.

An input or an output between channels in the neural network 110 may be expressed as a weighted sum between an input i and a weight w. The weighted sum is a multiplication operation and an iterative addition operation between a plurality of inputs and a plurality of weights, and may also be referred to as a “multiply and accumulate (MAC) operation”. Since a MAC operation is performed using a memory to which a computing function is provided, a circuit for performing a MAC operation may be referred to as an “in-memory computing (IMC) circuit”.

The neural network 110 may exchange numerous data sets between mutually connected channels and perform an operation process through a layer. In this operation process, numerous MAC operations are performed, and, in the case of a Von Neumann architecture (a processor cooperating with a main memory via bus), a number of memory access operations may be performed together to load activations and weights that are operands for the MAC operations at appropriate points in time.

In contrast to the Von Neumann architecture, according to an example, an IMC processor may include a MAC macro in which the memory array 130 is configured with a crossbar array structure.

The memory array 130 may include word lines 131, bit cells 133, and bit lines 135.

The word lines 131 may be used to receive input data of the neural network 110. For example, there may be N word lines 131, and a value corresponding to the input data of the neural network 110 may be applied to the N word lines.

The plurality of word lines 131 may intersect with the plurality of bit lines 135. For example, when the plurality of bit lines 135 are M bit lines, the bit lines 135 and the word lines 131 may intersect at N×M intersecting points (reflecting the crossbar structure of the memory array 130).

Meanwhile, the bit cells 133 may be disposed at the respective intersecting points of the word lines 131 and the bit lines 135. Each of the bit cells 133 may be implemented as, for example, volatile memory such as static random-access memory (SRAM) to store weights. However, examples are not limited thereto. According to an example, each of the bit cells 133 may be implemented as non-volatile memory such as resistive random-access memory (ReRAM), eFlash, non-volatile SRAM (nvSRAM), or the like.

The word lines 131 may be referred to as “row lines” in that, by convention, they correspond to rows that are arranged in a horizontal direction in the memory array 130. The bit lines 135 may be referred to as “column lines” in that they, by convention, correspond to columns that are arranged in a vertical direction in the memory array 130. Hereinafter, the terms “word line(s)” and “row line(s)” are used interchangeably. Further, the terms “bit line(s)” and “column line(s)” are used interchangeably.

The word lines 131 may sequentially receive the value corresponding to the input data of the neural network 110. In this case, the input data may be, for example, input data included in an input feature map or a weight value stored in a weight map.

For example, when an input signal IN_1 for the IMC device is “1” or “high”, the input signal IN_1 may be applied to a first word line of the memory array 130 in a first cycle corresponding to the input signal IN_1. When an input signal IN_2 for the IMC device is “0” or “low”, the input signal IN_2 may be applied to a second word line of the memory array 130 in a second cycle corresponding to the input signal IN_2. It may be noted that IN_1 and IN_2 are independent.

Sequentially inputting the input signals for the IMC device to the word lines 131 may be intended to prevent two or more input signals from colliding on a same bit line. If no collision occurs on a same bit line, the IMC device may simultaneously input two or more input signals to the word lines 131.

Each of the bit cells 133 of the memory array 130 may be disposed at an intersecting point of a word line and a bit line corresponding to the bit cell. Each of the bit cells 133 may store data corresponding to 1 bit. Each of the bit cells 133 may store weight data of a weight map or input data of an input feature map, for example, although it should be appreciated that MAC operations have other applications.

If a weight corresponding to a bit cell (i, j) is “1”, the bit cell (i, j) disposed at an intersecting point of a corresponding word line i and a corresponding bit line j transmits an input signal input to the corresponding word line to the corresponding bit line. If a weight corresponding to a bit cell (i+1, j+1) is “0”, an input signal may not be transmitted to a corresponding bit line even when the input signal is applied to a corresponding word line.

In the example of FIG. 1, at the right side, a weight corresponding to a bit cell (1, 1) corresponding to a first word line and a first bit line is “1” (as indicated by the circle at the intersection). Thus, the bit cell may be disposed at an intersecting point of the first word line and the first bit line. In this case, the input signal IN_1 input to the first word line may be transmitted to the first bit line.

As another example, a weight corresponding to a bit cell (1, 3) corresponding to the first word line and a third bit line is “0”. Thus, the bit cell disposed at the intersecting point of the first word line and the third bit line, by virtue of storing a “0”, may cause the input signal IN_1 input to the first word line to not be transmitted to the third bit line.

The bit cells 133 may also be referred to as “memory cells”. The bit cells 133 may include, for example, any one or any combination of a diode, a transistor (e.g., a metal-oxide-semiconductor field-effect transistor (MOSFET)), a static random access memory (SRAM) bit cell, and/or a resistive memory. However, examples are not limited thereto. Hereinafter, a case of the bit cells 133 being SRAM bit cells will be described as an example. However, examples are not limited thereto.

The bit lines 135 may intersect with the word lines 131, and each of the bit lines 135 may output a value received from a corresponding input line through a corresponding bit cell.

Among the bit cells 133, bit cells disposed along a same word line may receive the same input signal, and bit cells disposed along a same bit line may transmit the same output signal.

Considering the bit cells 133 disposed in the memory array 130 illustrated as an example in FIG. 1, the IMC device may perform a MAC operation as in Equation 2.

$$[ \begin{matrix}OUT\_ 1 \\ OUT\_ 2 \\ OUT\_ 3 \\ OUT\_ 4 \\ OUT\_ 5\end{matrix} ] = [ \begin{matrix}1 & 0 & 1 & 0 & 1 \\ 1 & 1 & 0 & 0 & 1 \\ 0 & 0 & 1 & 0 & 0 \\ 1 & 1 & 0 & 1 & 0 \\ 0 & 1 & 0 & 0 & 0\end{matrix} ] [ \begin{matrix}IN \_ 1 \\ IN \_ 2 \\ IN \_ 3 \\ IN \_ 4 \\ IN \_ 5\end{matrix} ] \qquad Equation 2$$

Bitwise multiplication operations may be performed and accumulated by bit cells included in the memory array 130 of the IMC macro, whereby a MAC operator, e.g., for AI acceleration, may be implemented.

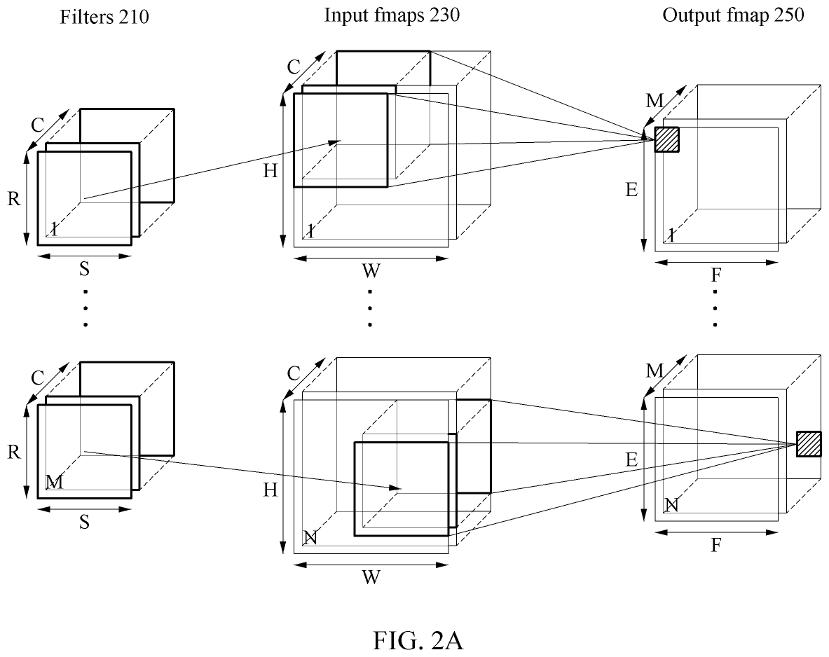

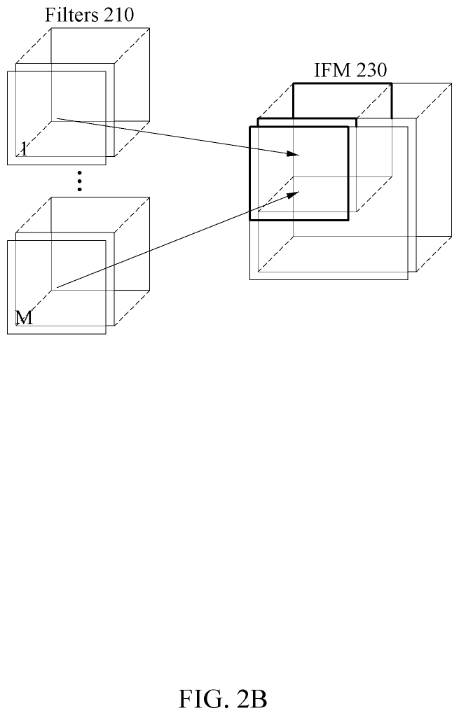

FIG. 2A illustrates an example of a data flow when a convolution operation is performed by an IMC processor, and FIG. 2B illustrates an example of reusing input data in a convolution operation.

Referring to FIG. 2A, filters 210 for a convolution operation, input feature maps (IFMs) 230, and output feature maps (OFMs) 250 are shown. For purposes of a MAC operation, filters and weight maps are functionally analogous (e.g., both may be MAC operands), and therefore, in some contexts, the terms “filter” and “weight map” may be used interchangeably. In some areas of machine learning technology, weights or weight maps may have specific meanings. Here, however, “filter” is used to represent two-dimensional (2D) weights such as a 3×3 matrix. On the other hand, “weight map” is used to refer to a weight matrix (or volume) such as one having 64 kernels, a 3×3 space, and 128 channels (a 64×3×3×128 weight map). The term 2D “filters” represents 128 3×3 elements of weights. Thus, “filter” refers to 2D weight elements in a weight map, and 2D filters in 210 refers C EA filters (i.e., 3D filters).

In FIG. 2A, R and S denote the height and the weight of each of the 2D filters 210. M denotes the number of 2D filters 210. Further, C denotes the number of input channels of a 2D input feature map IFM 230, and H and W denote the height and the width of the 2D input feature map IFM 230, respectively. In addition, E and F denote the height and the weight of a 2D OFM 250, respectively.

For example, a convolutional neural network (CNN) may include several convolutional layers. Each of the convolutional layers may generate a continuous, high-level abstracted value including unique information of input data. In this case, the abstracted value corresponding to the input data may be referred to as an “input feature map IFM”.

When there are multiple feature maps and/or filters, each of the feature maps or filters may be called a “channel”. In FIG. 2A, the number of channels of the filters 210 may be C, and the number of channels of the input feature maps IFMs 230 may be C. The number of channels in the output feature maps may be M. In FIG. 2A, N output feature maps 250 may be generated by convolution operations between the M filters 210 and the N input feature maps 230.

The convolution operations may be performed by shifting the filters 210 of a predetermined size (e.g., Rx S) by a pixel or stride of the input feature map IFM 230. The filters 210 and the input feature maps 230 presumably have one-to-one correspondence according to the definition of convolution, the number of filters 210 and the number of channels of the input feature maps 230 may be the same, “C”. The number of filters 210 and the number of channels of the output feature maps 250 may also be the same, i.e., M. The number of filters 210 and the number of channels of the output feature maps 250 may both be M because, per channel, as many output feature maps as input feature maps may be generated when a convolution operation between the input feature maps 230 and any one filter is performed.

A convolution operation may be performed largely by (i) reading data from an external memory (e.g., a DRAM device outside the main processor, e.g., a CPU) to an IMC memory device, (ii) having IMC macros of the IMC memory device perform MAC operations on the data, and (iii) storing results of MAC operations into a buffer or a register. In this case, retrieving data from the external memory device (e.g., DRAM) may require a long time and a considerable amount of power. Accordingly, the data retrieved from the external memory device may be reused (e.g., in the IMC memory device) to reduce the time and power consumption of re-retrieving the data.

Data reuse may be of three types, for example, convolutional reuse, weight data reuse, and/or input data reuse, in correspondence with which data is reused.

The convolutional reuse type may involve re-using both input data of input feature maps and weight data of weight maps. With the convolutional reuse type, the weight maps as many as the number of output feature maps may be reused, and the input feature maps as many as the number of weight maps may be reused. To expand, for the weight maps, the maximum number of reuses is the number of elements in corresponding output feature maps. On the other hand, for the input feature maps, the maximum number of reuses is the number of elements of the weight feature maps.

The weight data reuse type may involve a weight stationary dataflow in that weight data of weight maps is fixed and reused. With the weight data reuse type, the weight maps may be reused more as the number of batches of the input feature maps increases.

Input data reuse type may be stationary with respect to dataflow in that input data of input feature maps are relatively fixed and therefore may be reused. With the input data reuse type, the elements of the input feature maps may be reused as many as M (denoted in FIG. 2B). An example of reusing input data is described with reference to FIG. 2B.

Referring to FIG. 2B, an example of reusing input data of one of the input feature maps IFMs 230 as many times as the number of (e.g., M) channels of the filters 230 is shown.

For example, when input data of an input feature map IFM 235 is reused, the input data of the input feature map IFM 235 may be previously stored in a memory array of (or having) an IMC macro. As the data (weight data) stored in the filters 210 are applied to the memory array, a convolution operation may be performed in bit cells of the memory array.

The convolution operation may be performed in a manner that a filter 210 performs an operation by shifting data of any one input feature map stored in the memory array by one bit or by one stride. The stride may correspond to the number of bytes from one word line to a next word line of the bit cells of the memory array.

A partial sum corresponding to the result of a convolution operation may be stored in bit cells of a corresponding memory array that performs the convolution operation. The accumulation of the partial sum may be maintained in each of such bit cells accumulation may continue therein until the final sum of the convolution operation reaches the output feature map 250, thereby reducing the operation of reading and/or writing the partial sum.

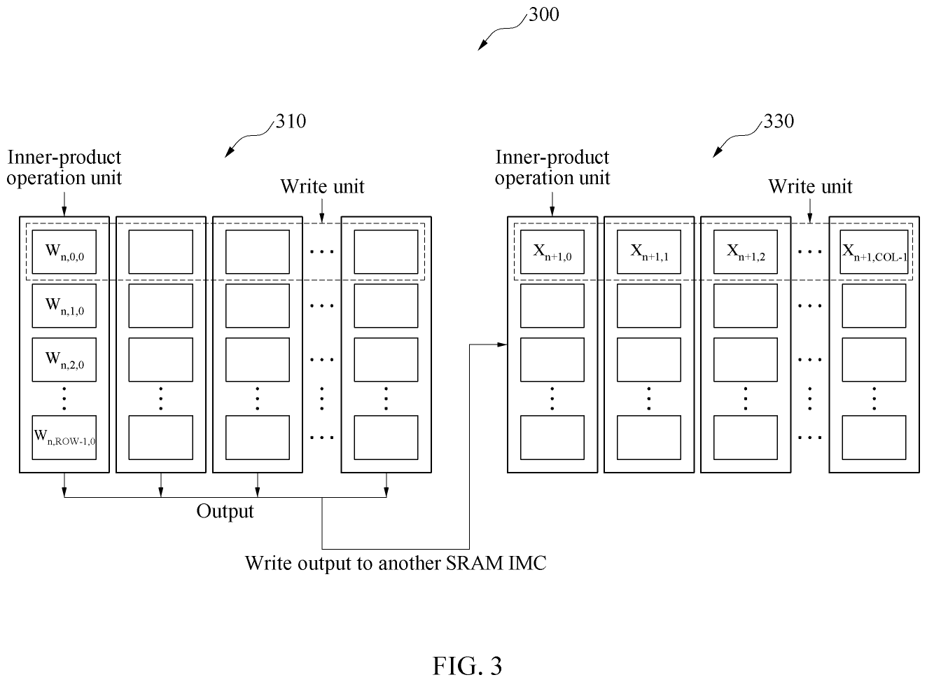

FIG. 3 illustrates an example of using an output of a previous IMC macro for a next IMC macro as it is, in an in-memory computing macro having a general structure (i.e., details or structure of the IMC macro are not important). FIG. 3 shows an example 300 of writing outputs of bit cells of a first IMC macro 310 (i.e., computation results) to a second IMC macro 330.

IMC technology may generally use a structure that obtains a calculated output by applying data of an input feature map (IFM) to a memory in which weights are stored in advance and which (the memory) is capable of computation. That is, many IMC-based AI processors may use a weight stationary dataflow where a weight map is stationary in memory and filters change.

For example, when an SRAM IMC macro is used, weight data may be read from a separate storage (e.g., a main memory) and written to the SRAM IMC macro at each power-on point in time (when the device is turning on), since SRAM is a volatile memory.

As shown in FIG. 3, the result of the convolution operation may be stored in the memory array of the first IMC macro 310 and then written to the second IMC macro 330 and used thereby as it is. In this case, the unit (or direction) of reading/writing the operation result stored in the memory array of the first IMC macro 310 from/to the memory array of the second IMC macro 330 may be in a row direction (i.e., in units of rows or portions of rows, consecutively). Conversely, the unit (or direction) of performing an operation (e.g., an inner-product operation) between (i) the data stored in the memory array of the second IMC macro 330 and (ii) retrieved data may be in a column direction. As shown in FIG. 3, when the direction in which data is read/written from/to the memory array does not match the direction in which the operation is performed, it may not be easy to perform an operation between IMC macros (e.g., computationally consecutive IMC macros exchanging a result) using a feature map (rather than weight data) as it is; the feature map may be an intermediate output of the convolution operation. To elaborate, when an input feature map written from a previous layer is stored in an IMC device, the data stored in the IMC device may not match with the computing unit (or direction) to be processed. Consider an example where a first IMC device (or macro) computes in the column direction. Weight elements in column 0 are computed with inputs (# of rows) and the IMC device/macro gives an output at column 0. The first IMC device/macro computes outputs for layer n, and stores the same to a second IMC device/macro for subsequent operation for layer n+1. However, since the stored data does not match to the direction of computing of the first IMC device/macro (i.e., column direction), the second IMC device/macro cannot perform operations as intended.

In an example, the volatile characteristic of SRAM may be utilized, and an operation may be enabled between IMC macros using a feature map which is an intermediate output of a convolution operation as it is (i.e., in-place without transformation, e.g., transposition), whereby data movement when multiple layers of a neural network are connected may be minimized.

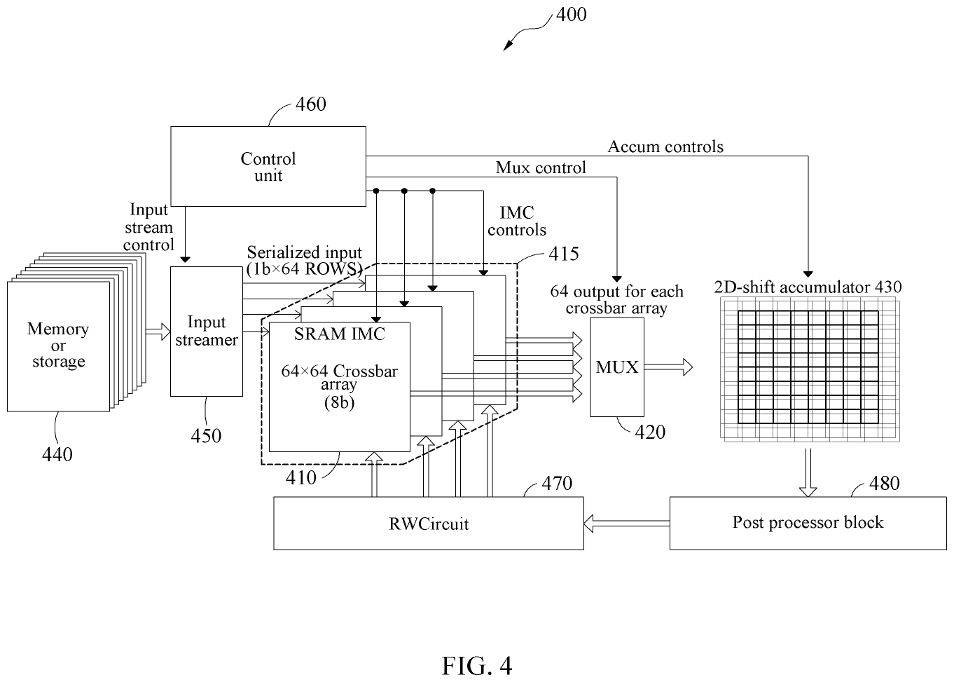

FIG. 4 illustrates an example of a hardware structure of an IMC processor. The IMC processor may also be referred to as memory with in-memory computing, or the like, with the hardware structure having memory (e.g., SRAM) as well as circuitry (e.g., IMC-related components) for performing computation directly on the memory. Referring to FIG. 4, an IMC processor 400 may include an SRAM IMC device 415, a multiplexer (MUX) 420, a 2D shift accumulator 430, memory devices 440, an input streamer 450, a control unit 460, a read write (RW) circuit 470, and a post processor block 480.

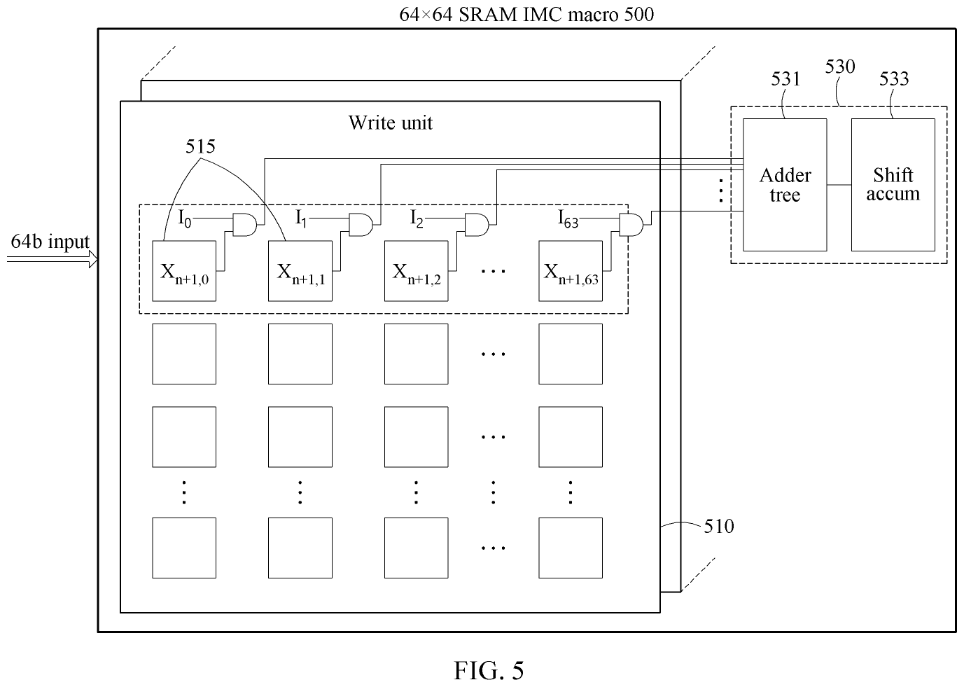

The SRAM IMC device 415 may include IMC macros 410. The IMC macros 410 may be, for example, SRAM IMC macros. However, examples are not limited thereto. Each of the IMC macros 410 may have a write/read direction and an operation direction that are the same, and may have a form in which memory banks of multiple memory arrays (e.g., memory arrays 510 of FIG. 5) share a single digital operator (e.g., a digital operator 530 of FIG. 5). The multiple memory arrays may have, for example, a crossbar array structure (discussed above). However, examples are not limited thereto.

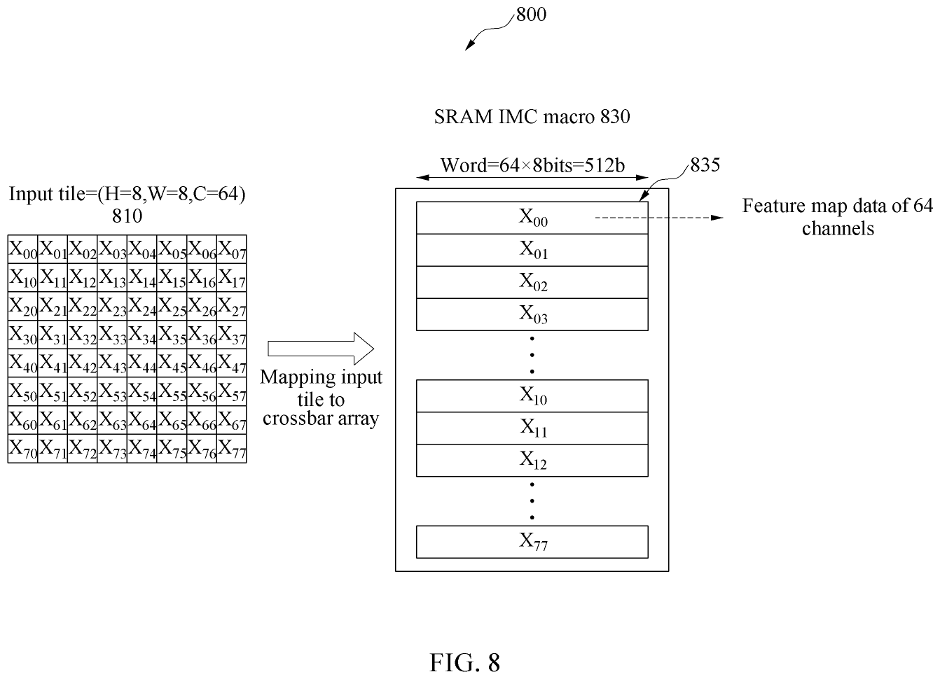

The SRAM IMC device 415 may perform a MAC operation between input data and weight data pre-applied to a first IMC macro 410, and may perform the MAC operation in a specific direction, which is a direction in which data is written to the first IMC macro. The input feature map may include, for example, 2D input data corresponding to word lines and bit lines of a first memory array included in the first IMC macro. The example of storing input data of an input feature map in an IMC macro is described in more detail with reference to FIG. 8. The MAC operation may be a linear operation or a convolution operation. However, examples are not limited thereto.

For example, an output end of the first IMC macro may be connected to an input end of a second IMC macro. In this case, the SRAM IMC device 415 may write data of an output feature map outputted/generated by the first IMC macro as input data to a second memory array of the second IMC macro, and may do so in the first direction and in parallel (e.g., the computing of the first IMC macro and the writing to the second IMC macro may be pipelined). Further, the SRAM IMC device 415 may perform, in response to second weight data of a second weight map being applied to the second IMC macro, a MAC operation between the data written to the second memory array (intermediate/feature map data from the first IMC macro) and the second weight data in the first direction. To reiterate, the data written to the second memory array may correspond to an operation result stored in bit cells of the first IMC macro, that is, data of an output feature map output by the first IMC macro.

For example, the SRAM IMC device 415 may store the output of the first IMC macro directly in another IMC macro (e.g., the second IMC macro), and thus may perform an operation on the data stored in the second macro without additional data movement.

The IMC macros 410 may express all data as digital logical values such as, for example, “0” and/or “1” to perform an operation. Further, input data, weight data, and output data in the IMC macros 410 may have a binary format.

The IMC macros 410 may share the 2D shift accumulator 430. The IMC processor 400 may perform a larger inner product operation (compared to that capable of being performed by only one IMC macro) by having the IMC macros 410 share the 2D shift accumulator 430. The structure of the IMC macros 410 is described in more detail with reference to FIG. 5.

The MUX 420 may selectively transmit outputs of memory arrays of the IMC macros 410 to the 2D shift accumulator 430, according to a control signal from the control unit 460.

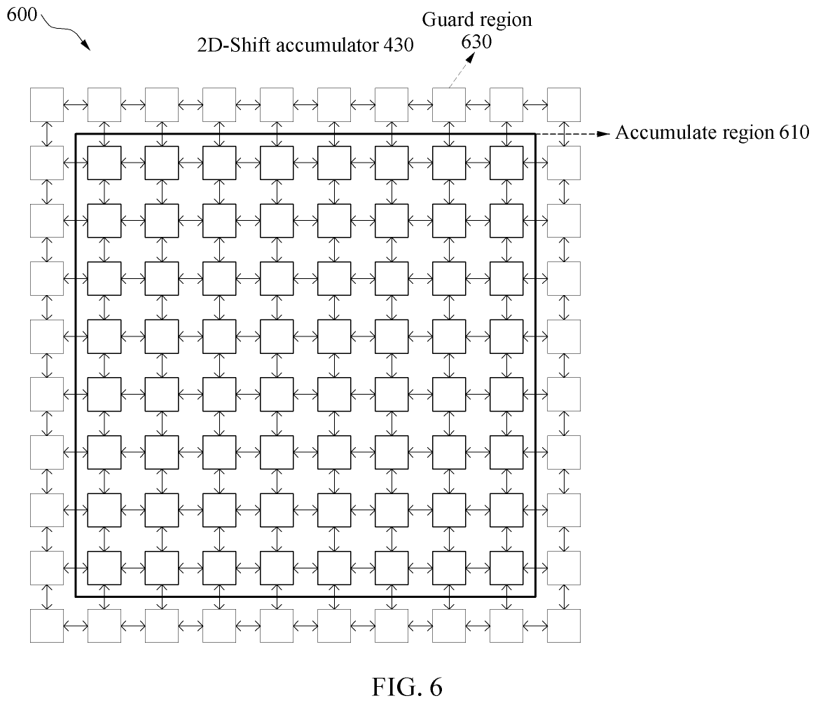

The 2D shift accumulator 430 may receive the outputs of the IMC macros 410 and perform a shift operation with accumulation. The 2D shift accumulator 430 may perform a shift operation on partial sums corresponding to respective MAC operation results of the IMC macros 410 and accumulate a result of the shift operation (e.g., with a previous result, hence, accumulation). For example, the 2D shift accumulator 430 may store the result of accumulation in a buffer and/or an output register. However, examples are not limited thereto. The structure and operation of the 2D shift accumulator 430 is described in more detail with reference to FIG. 6.

The memory devices 440 may store weight data of weight maps respectively corresponding to the IMC macros 410. The memory devices 440 may have a non-volatile characteristic. The memory devices 440 may be non-volatile memory such as, for example, flash memory, magnetic random-access memory (MRAM), phase-change RAM (PRAM), and/or resistive RAM (RRAM). However, examples are not limited thereto.

The input streamer 450 may delay weight data of a weight map corresponding to each of the IMC macros 410 by a unit cycle and apply the delayed weight data to the corresponding IMC macro.

The input streamer 450 may read, from the memory devices 440, weight data of weight maps corresponding to one or more IMC macros that are operable at the same time among the IMC macros 410. For example, the input streamer 450 may read the weight data of the weight maps stored in the memory devices 440 or may read the weight data from weight maps stored in a weight buffer.

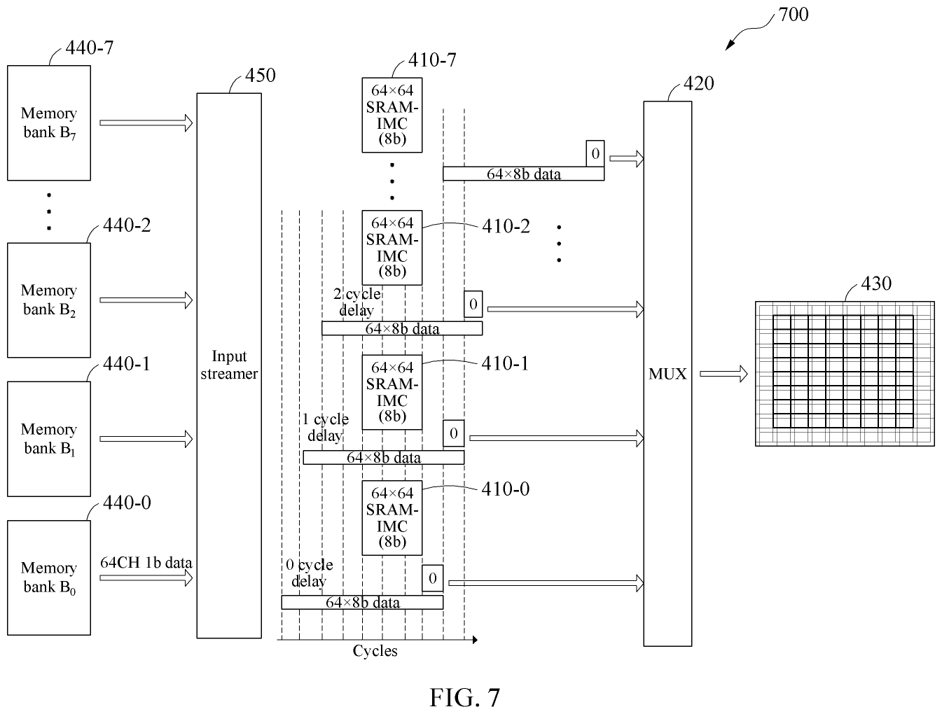

The input streamer 450 may apply the read weight data to the corresponding IMC macro at a point in time delayed by the unit cycle (a cycle for the units of data sequentially streamed from a weight map), for each of the one or more IMC macros. The operation of the input streamer 450 is described in more detail with reference to FIG. 7.

The control unit 460 may generate and transmit control signals for the operation of the components of the IMC processor 400 according to clock signals. For example, the control unit 460 may generate and/or transmit control signals for the IMC macros 410, the MUX 420, the 2D shift accumulator 430, and the input streamer 450.

The RW circuit 470 may write data to the IMC macros 410 or read data stored in the IMC macros 410. The RW circuit 470 may read and write data of one or more bit cells (e.g., bit cells 515 of FIG. 5) included in a memory array of each of the IMC macros 410. The data of the one or more bit cells may include, for example, input data values multiplied by weight data (e.g., data of a MAC operation in progress). For example, the RW circuit 470 may access the bit cells of the memory array through bit lines (sometimes referred to herein as RBL and RBLB) of the memory array portions of the IMC macros 410. To access the bit cells of a memory array, the RW circuit 470 may access a bit cell connected to an activated word line among a word lines RWL of the memory array. Thus, the RW circuit 470 may access a bit cell to write (store) data to the accessed bit cell or read data stored in the accessed bit cell.

The post processor block 480 may correspond to a vector processor or a hardware (HW) accelerator that performs operations other than vector-matrix multiplication (VMM). For example, the post processor block 480 may perform element-wise multiplication, element-wise addition, batch normalization, non-linear function, and/or pooling on an operation result of VMM, that is, an operation result for different filters. However, examples are not limited thereto. The post processor block 480 may have separate digital logic capable of performing some or all such post processing operations.

The IMC processor 400 may be integrated into a device, for example, a mobile device, a mobile computing device, a mobile phone, a smart phone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, a medical device, or the like.

The IMC processor 400 may directly perform an operation in the memory in a state in which input data can continuously change periodically (e.g., with a clock cycle or at periods driven thereby) and is stored in the memory arrays of the IMC macros 410 for inference, thereby reducing power consumption while greatly reducing the memory bandwidth as well. Further, the IMC processor 400 may operate a larger network at the system level based on the SRAM IMC device 415. That is, the size of neural network that can be processed by the IMP processor 400 can be adjusted by scaling size of the SRAM IMC device 415.

For example, if a 64×64 IMC processor performs a dot product for a 64-bit vector, and an operation to be performed is a dot product for a 256-bit vector, each of the four IMC processors 410 (for example) may compute the dot product for the 64-bit vector, such that computation results may be summed to obtain an operation result of the dot product of the 256-bit vector. In an example, the operation result of the dot product for the 64-bit vector may be accumulated in the 2D shift accumulator 430 through the time delay of the input streamer 450, and thus, linear layers of a large input channel streamed in units to multiple SRAM IMC macros may be effectively performed. In addition, the IMC processor 400 may effectively perform a convolution operation in a state in which the input data of an input feature map is stored. Also, the IMC processor 400 may effectively operate various types of convolutional layers by controlling a shift operation by the structure of the IMC macros 410 sharing the 2D shift accumulator 430. Furthermore, the IMC processor 400 may directly store input feature maps in the IMC macros and thus, may be implemented as a low-power AI accelerator by reducing the data movement otherwise needed for performing digital operations/computations.

FIG. 5 illustrates an example structure of an IMC macro of a static random-access memory (SRAM) IMC device, according to one or more embodiments. Referring to FIG. 5, the structure of an IMC macro 500 among the IMC macros 410 is shown.

Hereinafter, for ease of description, an example of input data being 8 bits long and weight data being 8 bits long will be assumed. However, examples are not limited thereto. The input data and the weight data may be 4 bits, 16 bits, or 32 bits long, for example.

The IMC macro 500 may have a write/read direction and an operation direction that are the same, and may have a form in which memory banks of the multiple memory arrays 510 share the single digital operator 530. The IMC macro 500 may include the memory arrays 510 and the digital operator 530.

A memory array 510 may include a bit cells 515. Bit cells connected to a same bit line of the memory array 510 may be able to receive the same 1-bit weight data. The memory array 510 may perform an AND operation between input data stored in a corresponding bit cell and weight data corresponding to each of the bit cells 515. In this case, the stored data is elements of an input feature map (i.e., the aforementioned “input data” is data inputted to an input layer of a neural network). Thus, the stored data is computed with input driven to the IMC macro (here, the input of IMC macro is elements of weights).

The memory array 510 may include a word lines, a bit lines intersecting with the word lines, and a bit cells 515 disposed at points where the word lines intersect the bit lines. The memory array 510 may include, for example, sixty-four word lines and sixty-four bit lines. In this case, the size of the memory array 510 may be expressed as 64×64. The word lines and the column lines in the memory array 510 may be implemented by changing each other. To explain further, the direction of writing and computing can be changed. Thus, two cases are possible. In case (1) writing and computing can be performed column-wise (writing a unit of data, 32 for example, results in storing data to row 0 to row 31 at column x). In case (2) writing and computing can be performed rows-wise (writing a unit of data, 32 for example, results in storing data to column 0 to row 31 at row x). Examples are not limited thereto.

Each of the bit cells 515 may store an input feature map or weight data. Data stored in the bit cells 515 may be transmitted through, for example, the RW circuit 470.

The digital operator 530 may accumulate a result of the AND operation corresponding to each of the bit cells 515 of the memory array 510. The digital operator 530 may include, for example, an adder (e.g., an adder tree) 531 for performing an add operation on the result of the AND operation, and a shift accumulator 533 for sequentially accumulating a result of the add operation of the adder 531 through a bit-shift operation.

The adder 531 may be connected to an output end of the memory array 510 to perform an add operation on signals output from the memory array 510. The adder 531 may be implemented as, for example, a full adder, a half adder, and/or a flip-flop. The adder 531 may correspond to, for example, a digital adder such as an adder tree circuit or an adder tree. However, examples are not limited thereto.

For example, for an operation on 64-bit input data stored in one word line of the memory array 510, sixty-four 1-bit weight data may be applied to the IMC macro 500 in every cycle over eight cycles. Accordingly, the 64-bit weight data may be applied to the memory array 510, and an AND operation between the input data stored in the memory array 510 and the weight data may be performed.

64-bit AND operation results of the same word line may be summed through the adder 531, and a final result may be output for eight cycles through the shift accumulator 533 through shift and accumulate operations on a result of the summation.

The shift accumulator 533 may output a final MAC operation result by shifting bit positions corresponding to the same word line by a predetermined bit (e.g., one bit), applying the same to the summation result output from the corresponding word line, and accumulating the values whose bit positions are shifted.

FIG. 6 illustrates an example structure and operation of a two-dimensional (2D) shift accumulator. Referring to FIG. 6, a connection structure 600 of buffers included in the 2D shift accumulator 430 is shown. Each of the squares connected to each other may correspond to a respective single buffer. The size of a single buffer may be the number of bits of output elements of an IMC macro+alpha (α) (e.g., 17 bits). For example, a calculation result of 8-bit input data and 8-bit weight data may be 16 bits long. Further, a result of adding sixty-four 16-bit calculation results may be 22 bits long. Therefore, 22 bits may be used to store the result of adding 64 operation results without loss. In this case, it may be assumed that the above-described operation is accumulated and performed several times by the 2D shift accumulator 430, and a size of 22 bits or longer may be required. For example, a size of 25 bits may be used for each buffer to guarantee no loss up to eight times of accumulation. The aforementioned alpha (α) may correspond to the number of bits used to smoothly perform an accumulate operation by the 2D shift accumulator 430, in addition to the number of bits of the output elements.

The 2D shift accumulator 430 may perform an accumulate operation on partial sums corresponding to MAC operation results of a IMC macros by performing the shift operation on the respective MAC operation results of the IMC macros in a direction that may up, down, left, or right.

The 2D shift accumulator 430 may receive inputs that are as many as the number of outputs of the IMC macro (e.g., sixty-four inputs) through the MUX 420, and store the inputs in buffers of the shift accumulator arranged in two-dimension (e.g., 10×10) or accumulate the inputs in a previously calculated value. The 2D shift accumulator 430 may simultaneously perform shift operations in up, down, left, and right directions in every cycle, in addition to the accumulate operation.

The 2D shift accumulator 430 may include, for example, a quantity of buffers having a total size of 10×10, which is larger than the 8×8 size of the IMC macro. The buffers may include a first region 610 (interior 8×8 region) for receiving outputs of the IMC macros (MAC operation results corresponding to the IMC macros) and storing and/or accumulating the outputs, and a second region 630 (perimeter region) for preventing data loss due to the shift operation. The first region 610 may be referred to as an “accumulate region” in that it is a region for accumulating operation results. Further, the second region 630 may be referred to as a “guard region” in that it is a region for guarding data produced by the shift operation.

The single buffers in the 2D shift accumulator 430 may receive the same control signal from a control unit (e.g., the control unit 460 of FIG. 4) in the same cycle and perform the shift operation in one direction.

The single buffers may all move in the same direction according to the same control signal. For example, the single buffers may receive the same control signal and perform the shift operation in one direction when accumulating operation results, or may receive the same control signal and perform writing in one direction when simply writing operation results without accumulating the operation results.

The size of the first region 610 and the size of the second region 630 may be determined based on the size of the IMC macro. The size of the first region may be the same as the size of the IMC macro (e.g., 1 buffer per one bit cell), or may be larger than a first size of the IMC macro so as to perform an operation of a larger size compared to the first size of the IMC macro. For example, the size of the second region 630 may be fixed to 2 bits or 4 bits according to the range and/or direction of the shift operation to be performed, or may be variable.

FIG. 7 illustrates an example of an operation of an input streamer, according to one or more embodiments. Referring to FIG. 7, an example 700 of performing a linear operation by eight IMC macros 410-1, 410-1, 410-2, . . . , and 410-7 sharing the input streamer 450 and the 2D shift accumulator 430 is shown.

The input streamer 450 may read weight data corresponding to an input from a memory banks 440-0, 440-1, 440-2, . . . , and 440-7 of the memory device(s) 440 and apply the weight data to the respective 8-bit IMC macros 410-0, 410-1, 410-2, . . . , and 410-7 constituting one group.

For example, when the size of the IMC macro 410 is 64×64 and the input data is 8 bits long, the input streamer 450 may read 64-channel 1-bit data, that is, 64-bit weight data, from each of the memory banks 440-0, 440-1, and 440-2, . . . , and 440-7 of the memory device 440.

The input streamer 450 may apply the read 64-bit data to each of the IMC macros 410-0, 410-1, 410-2, . . . , and 410-7 in every cycle. At this time, since the IMC macros 410-0, 410-1, 410-2, . . . , and 410-7 are 8 bits wide, eight cycles may be used to apply the 64-bit data read by the input streamer 450 to all of the IMC macros 410-0, 410-1, 410-2, . . . , and 410-7.

The input streamer 450 may obtain sixty-four partial sums corresponding to outputs of the IMC macros 410-0, 410-1, 410-2, . . . , and 410-7 by applying the read 64-bit weight data to the IMC macros 410-0, 410-1, 410-2, . . . , and 410-7 over eight cycles.

At this time, the input streamer 450 may read, from the memory banks 440-0, 440-1, 440-2, . . . , and 440-7 of the memory device(s) 440, data (e.g., weight data) to be used by N G (e.g., eight) IMC macros that are operable at the same time among the 8-bit IMC macros 410-0, 410-1, 410-2, . . . , and 410-7 constituting one group. The input streamer 450 may apply the read data to each of the IMC macros 410-0, 410-1, 410-2, . . . , and 410-7 at a point in time delayed by a unit cycle (e.g., one cycle), thereby enabling partial sums of different input channels to be summed by the 2D shift accumulator 430 without performance degradation.

One IMC macro may calculate a final output over eight cycles for the input 8-bit data (e.g., the weight data). Therefore, if N_{G}=8 where N_{G} denotes the number of IMC macros that are operable at the same time, the outputs of the eight IMC macros from SRAM_IMC_0 410-0 to SRAM_IMC_7 410-7 may be sequentially output without overlapping.

The output of each of the eight IMC macros may be output with delay by one cycle and then transmitted to the one shared 2D shift accumulator 430 through the MUX 420. The 2D shift accumulator 430 may perform an accumulate operation on the outputs of the eight IMC macros.

In general, a single 64×64 IMC macro performs an inner-product operation for a 64-bit vector. However, the IMC processor may configure the eight IMC macros constituting one group to share one 2D shift accumulator 430, thereby enabling an inner-product operation for a 512-bit vector, that is, 64-bit vector×8. The inner-product operation may correspond to a dot product operation of a matrix product for convolution.

In an example, by configuring a IMC macros to share one 2D shift accumulator 430, convolution may be implemented more efficiently by the same hardware structure. The example of performing an inner-product operation of a 512-bit vector is described in more detail with reference to FIG. 8.

FIG. 8 illustrates an example of storing input data in an IMC macro, according to one or more embodiments. Referring to FIG. 8, an example 800 of mapping and storing data of an 8×8 input tile 810 of feature map data, for example, to a memory array 835 of an IMC macro 830 is shown.

As described above, an IMC processor may perform a convolution operation without additional data movement in a state in which an output feature map OFM corresponding to an output of an n-th layer of a neural network is reused as an input feature map IFM of an n+1-th layer and stored in the memory array 835 of the IMC macro 830. At this time, the input feature map IFM of the n+1-th layer (the output feature map OFM of the n-th layer) may be applied in the form of an input tile as shown in FIG. 8 and stored in (or written to) the memory array 835 of the IMC macro 830.

For example, when the size of the input tile 810 is 8×8 and the number of channels is 64, X₀₀ among data of the input tile 810 may be mapped to and stored in or written to a first word line of the memory array 835 of the IMC macro 830. At this time, since the memory array 835 is configured with 8 bits and the number of channels is 64, one word line of the memory array 835 may correspond to a size of a 512-bit vector, that is, 8×64-bit vector.

Thereafter, X₀₁ among the data of the input tile 810 may be mapped to and stored in a second word line of the memory array 835, and X₀₂ among the data of the input tile 810 may be mapped to and stored in a third word line of the memory array 835. In the same manner, X₇₇ among the data of the input tile 810 may be mapped to and stored in a 64-th word line of the memory array 835.

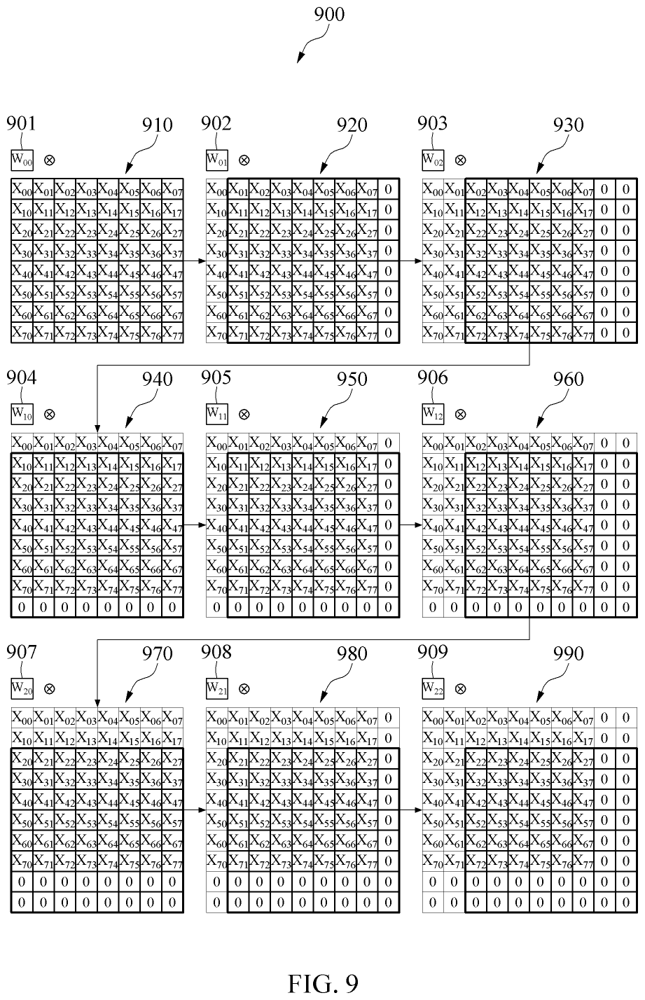

The example of performing a convolution operation for the input data, which is a 64-bit vector, stored in the memory array 835 is described in more detail with reference to FIG. 9.

FIG. 9 illustrates an example of performing a convolution operation in an IMC processor, according to one or more embodiments. Referring to FIG. 9, an example 900 of performing a 3×3 convolution operation in an IMC processor is shown.

As in the example described above, assuming an example of performing an operation between 8-bit weight data W and 8-bit input data X stored in a memory array, the operation between the 8-bit weight data and the 8-bit input data stored in the memory array may be performed over eight cycles, and an operation result may be transmitted to a 2D shift accumulator. At this time, the operation result corresponding to the number of word lines of the memory array may be transmitted to the 2D shift accumulator and accumulated in a first region (e.g., the first region 610 of FIG. 6) of a buffer (e.g., the buffer of FIG. 6) of the 2D shift accumulator.

The buffer of the 2D shift accumulator may be configured in a 2D form, and an operation result between input data X_{i,j} stored in the memory array and weight data W corresponding to the input data X_{i,j} may be accumulated in a i-th row and a j-th column of the first region 610 of the buffer. At this time, the operation between the input data X_{i,j} and the weight data W may not be a simple multiplication, but a result of an inner-product operation between a 64-bit vector 910 corresponding to the input data X_{i,j} and a 64-bit weight data 801 as shown in FIG. 9.

Each of the examples 910, 920, 930, 940, 950, 960, 970, 980, and 990 of FIG. 9 show a region where an inner-product operation between a 64-bit input X_{i,j} stored in the memory array of the IMC macro and weight data W_{hw} is performed, for example, to perform a 3×3 convolution, in the buffers of the 2D shift accumulator. The 2D shift accumulator may obtain a result of the convolution operation by summing all the results shown in the nine examples 910, 920, 930, 940, 950, 960, 970, 980, and 990.

In an example, configuring the 2D shift accumulator to shift an operation result (e.g., a partial sum) up, down, left, and right in each cycle may enable results of the convolution operation to be summed by a shift operation on the partial sum of each operation, without changing input data.

For a 3×3 convolution operation, the values of nine pieces of weight data W₀₀ 901, W₀₁ 902, W₀₂ 903, W₁₀ 904, W₁₁ 905, W₁₂ 906, W₂₀ 907, W₂₁ 908, and W₂₂ 909 may be sequentially multiplied with the vectors in the example 910 corresponding to an input tile (e.g., the input tile 810 of FIG. 8) stored in the memory array and then, added to the first region of the buffers of the 2D shift accumulator. The 2D shift accumulator may perform a shift operation, for example, each time when each of the operations such as operations between one piece of weight data W₀₀ and 8×8 inputs (e.g., all Xs stored in SRAM) is finished. The 2D shift accumulator may obtain sixty-four outputs as the result of operations between one weight data W₀₀ and the 8×8 inputs (all Xs stored in SRAM). In other words, when nine operations corresponding to the nine pieces of weight data W₀₀ 901, W₀₁ 902, W₀₂ 903, W₁₀ 904, W₁₁ 905, W₁₂ 906, W₂₀ 907, W₂₁ 908, and W₂₂ 909 are finished, the 2D shift accumulator (or the buffers of the 2D shift accumulator) may be in a state of storing the sixty-four outputs with respect to the 3×3 convolution operation.

For example, for each of the single buffers shown in FIG. 6, the 2D shift accumulator may perform a shift operation by one cell in left direction->left direction->“right direction+right direction+down direction” over three cycles, then perform a shift operation in left direction->left direction->“right direction+right direction+down direction” over three cycles, and perform a shift operation in left direction->left direction again.

The 2D shift accumulator may perform a convolution operation for the 8×8 inputs with the weight data W₀₀, and then store the operation result in the buffers. In addition, during a convolution operation for the 8×8 inputs (all Xs stored in SRAM) with the weight data W₀₁, the 2D shift accumulator may be shifted to the right by one cell. By the shift, the result of the convolution operation of “weight data W₀₀ and input data X₀₀” may be positioned in the second buffer when viewed in the horizontal direction, and when the computation of the weight data W₀₁ and the 8×8 inputs (all Xs stored in SRAM) is finished, the result of “weight data W₀₁*input data X₀₁” may be accumulated in the second buffer. If the 2D shift accumulator shifts to the right again when the weight data W₀₂ is applied to the IMC macro, the operation result of “input data X₀₀*weight data W₀₀+input data X₀₁*weight data W₀₁” may be placed at the third position in the horizontal direction, and the operation result of weight data W₀₂*input data X₀₂ may be accumulated at the third position in the horizontal direction, and thus, “input data X₀₀*weight data W₀₀+input data X₀₁*weight data W₀₁+input data X₀₂*weight data W₀₂” may be accumulated in the third buffer. The 2D shift accumulator may shift (or move) to the left twice and then shift (or move) down, to adjust the position again when the weight data W₀₁ is applied.

In this case, the input data moved in the process of performing the shift operation may be temporarily stored in a second region (e.g., the second region 630 of FIG. 6) of the buffers of the 2D shift accumulator. According to the example of FIG. 9, the size of the second region 630 of the buffers may be 2 bits larger than the size of the first region 610 in width and height, respectively.

Since the operation result is output every 8 cycles for the 8-bit input data, the three cycles used for the shift operation in “right direction+right direction+down direction” described above may not degrade the operation performance of the IMC macro.

The IMC processor may perform convolution operations of various sizes in addition to the 3×3 convolution operation described with reference to FIG. 9. According to an example, the IMC processor may divide a single large image into input tiles and perform convolution operations thereon, and then perform an operation of combining operation results into one.

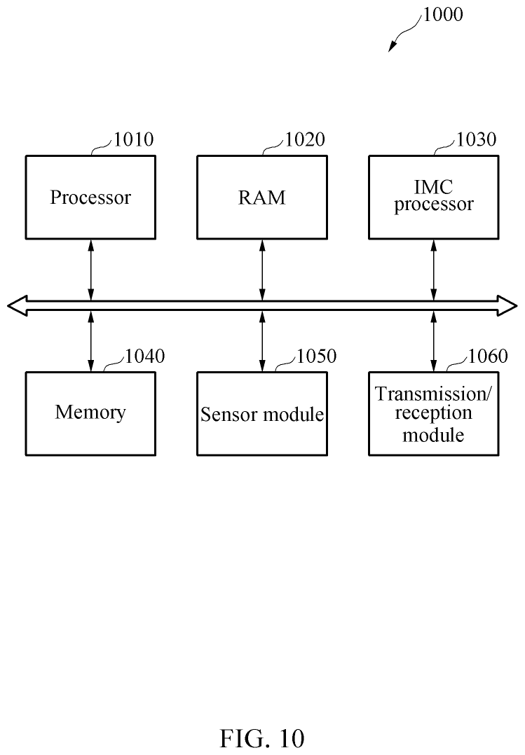

FIG. 10 illustrates an example of an electronic system including an IMC processor, according to one or more embodiments. Referring to FIG. 10, an electronic system 1000 may extract valid information by analyzing input data in real time based on a neural network (e.g., the neural network 110 of FIG. 1), and determine a situation based on the extracted information or control components of an electronic device on which the electronic system 1000 is mounted. For example, the electronic system 1000 may be applied to a mobile device, a mobile computing device, a mobile phone, a smart phone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, and a medical device, to name some examples, and may be mounted on at least one of other various types of electronic devices.

The electronic system 1000 may include a processor 1010, a random-access memory (RAM) 1020, an IMC processor 1030, a memory 1040, a sensor module 1050, and a transmission/reception module 1060. The electronic system 1000 may further include an input/output module, a security module, a power control device, and the like. A portion of hardware components of the electronic system 1000 may be mounted on at least one semiconductor chip.

The processor 1010 may control the overall operation of the electronic system 1000. The processor 1010 may include a single processor core (single core) or a plurality of processor cores (multi-core). The processor 1010 may process or execute programs and/or data stored in the memory 1040. In some examples, the processor 1010 may control the function of the IMC processor 1030 by executing the programs stored in the memory 1040. The processor 1010 may be implemented as a central processing unit (CPU), a graphics processing unit (GPU), an application processor (AP), and the like.

The RAM 1020 may temporarily store programs, data, or instructions. For example, the programs and/or data stored in the memory 1040 may be temporarily stored in the RAM 1020 according to control of the processor 1010 or a booting code. The RAM 1020 may be implemented as a memory such as, for example, dynamic RAM (DRAM) or static RAM (SRAM).

The IMC processor 1030 may perform an operation of the neural network based on the received input data, and generate various information signals based on a result of the operation. The neural network may be, for example, a convolutional neural network (CNN), a recurrent neural network (RNN), a fuzzy neural network (FNN), a deep belief network, a restricted Boltzmann machine, or the like. However, examples are not limited thereto. The IMC processor 1030 may be, for example, a hardware accelerator dedicated to the neural network and/or a device including the same. Here, the term “information signal” may include one of various types of recognition signals such as, for example, a voice recognition signal, an object recognition signal, a video recognition signal, and a biological information recognition signal.

The IMC processor 1030 may control SRAM bit cell circuits of an IMC macro to share and/or process the same input data, and select at least a portion of operation results output from the SRAM bit cell circuits.

For example, the IMC processor 1030 may receive or store, as input data, frame data included in a video stream, and generate a recognition signal about an object included in an image represented by the frame data from the frame data. Alternatively, the IMC processor 1030 may receive various types of input data and generate a recognition signal according to the input data based on a type or a function of the electronic system 1000 on which the IMC processor 1030 is mounted.

The memory 1040 is a storage configured to store data and may store an operating system (OS), various types of programs, and various types of data. In an example, the memory 1040 may store intermediate results generated in the process of performing an operation of the IMC processor 1030.

The memory 1040 may include any one or any combination of a volatile memory and a non-volatile memory (but not a signal per se). The non-volatile memory may include, for example, read-only memory (ROM), programmable read-only memory (PROM), erasable programmable read-only memory (EPROM), electrically erasable programmable read-only memory (EEPROM), flash memory, magnetic RAM (MRAM), phase-change memory (PRAM), resistive RAM (RRAM), and/or ferroelectric RAM (FRAM). However, examples are not limited thereto. The volatile memory may include, for example, dynamic RAM (DRAM), static RAM (SRAM), SDRAM, and the like. However, examples are not limited thereto. Depending on an example, the memory 1040 may include any one or any combination of a hard disk drive (HDD), a solid state drive (SSD), a compact flash (CF) card, a secure digital (SD) card, a micro-SD card, a mini-SD card, an extreme digital (xD) picture card, and a memory stick.

The sensor module 1050 may collect information around the electronic system 1000 on which the electronic system 1000 is mounted. The sensor module 1050 may sense or receive a signal (e.g., an image signal, an audio signal, a magnetic signal, a biosignal, a touch signal, etc.) from the outside of the electronic system 1000 and convert the sensed or received signal into data. The sensor module 1050 may include at least one of various types of sensing devices such as, for example, a microphone, an imaging device, an image sensor, a light detection and ranging (LIDAR) sensor, an ultrasonic sensor, an infrared sensor, a biosensor, and a touch sensor.

The sensor module 1050 may provide the converted data as input data to the IMC processor 1030. For example, the sensor module 1050 may include an image sensor, and may generate a video stream by photographing an external environment of the electronic system and sequentially provide consecutive data frames of the video stream as input data to the processor 1030. However, examples are not limited thereto, and the sensor module 1050 may provide various types of data to the IMC processor 1030.

The transmission/reception module 1060 may include various types of wired or wireless interfaces capable of communicating with an external apparatus. For example, the transmission/reception module 1060 may include a wired local area network (LAN), a wireless local area network (WLAN) such as wireless fidelity (Wi-Fi), a wireless personal area network (WPAN) such as Bluetooth, a wireless universal serial bus (USB), ZigBee, near field communication (NFC), radio-frequency identification (RFID), power line communication (PLC), a communication interface accessible to a mobile cellular network, such as 3rd Generation (3G), 4th Generation (4G), and Long Term Evolution (LTE), and the like.

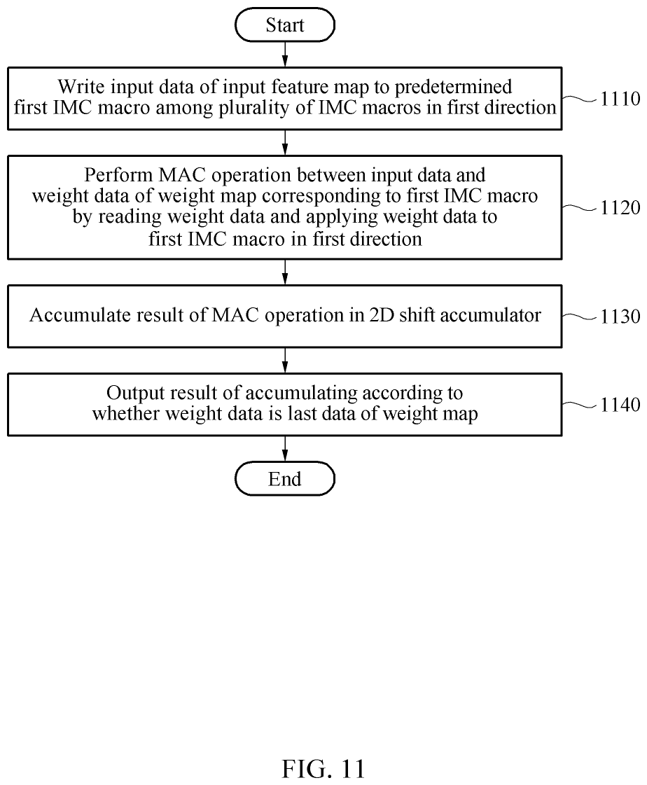

FIG. 11 illustrates an example of an operating method of an IMC processor, according to one or more embodiments. In the following examples, operations may be performed sequentially, but are not performed sequentially. For example, the operations may be performed in different orders, and at least two of the operations may be performed in parallel.

Referring to FIG. 11, the IMC processor may output a result of accumulation through operations 1110 to 1140.

In operation 1110, the IMC processor may write input data of an input feature map to a first IMC macro among IMC macros in a first direction. The IMC processor may write the input data of the input feature map to a first IMC macro in the first direction by a RW circuit.

In operation 1120, the IMC processor may perform a MAC operation between the input data and weight data of a weight map corresponding to the first IMC macro by reading the weight data and applying the weight data to the first IMC macro in the first direction. The IMC processor may read weight data from a weight map stored in a memory device and apply the weight data to a memory array of the first IMC macro in the first direction.

The IMC processor may delay a weight map corresponding to each of the IMC macros by a unit cycle and apply the delayed weight map to the corresponding IMC macro. More specifically, the IMC processor may read weights corresponding to one or more IMC macros that are operable at the same time among the IMC macros. The IMC processor may apply the read weight data to a memory array of the corresponding IMC macro in the first direction at a point in time delayed by the unit cycle, for each of the one or more IMC macros.

The IMC processor may iteratively read the weight data and apply the read weight data to a memory array of the first IMC macro in the first direction until a last bit of a column channel of the weight map stored in a memory device is reached.

In operation 1130, the IMC processor may accumulate a result of the MAC operation in a 2D shift accumulator.

In operation 1140, the IMC processor may output a result of the accumulating according to whether the weight data is last data of the weight map. In response to the weight data being the last data of the weight map, the IMC processor may output the result of the accumulating. Conversely, in response to the weight data not being the last data of the weight map, the IMC processor may read next weight data of the weight data from the weight map, apply the next weight data to the first IMC macro, and shift the result of the operation in the 2D shift accumulator.

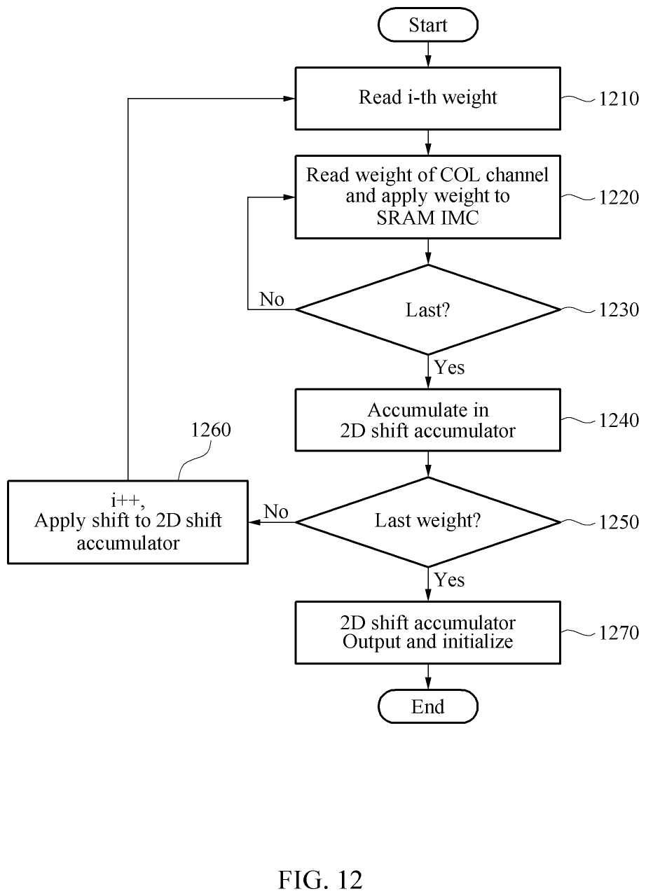

FIG. 12 illustrates an example of an operating method of an IMC processor, according to one or more embodiments. In the following examples, operations may be performed sequentially, but are not performed sequentially. For example, the operations may be performed in different orders, and at least two of the operations may be performed in parallel.

Referring to FIG. 12, the IMC processor may perform a convolution operation through operations 1210 to 1270. In this case, the number of input channels may be equal to the number of columns of a memory array of a SRAM IMC macro, and the number of weight maps may be 1.

In operation 1210, the IMC processor may read i-th weight data of a weight map.

In operation 1220, the IMC processor may read weight data of a column channel and apply the weight data to the SRAM IMC macro. In this case, input data may be previously stored in the memory array of the SRAM IMC macro. In response to the IMC processor applying the weight data, an operation (e.g., an AND operation) may be performed in the memory array of the SRAM IMC macro.

In operation 1230, the IMC processor may determine whether the operation has been performed up to a last bit of the memory array of the SRAM IMC macro.

In response to the determination in operation 1230 that the operation has not been performed up to the last bit, the IMC processor may read weight data and apply the weight data to the next bit of the memory array of the SRAM IMC macro through operation 1220.

In response to the determination in operation 1230 that the operation has been performed up to the last bit, the IMC processor may accumulate the operation result in the 2D shift accumulator, in operation 1240.

In operation 1250, the IMC processor may determine whether the corresponding weight data is the last weight data of the weight map.

In response to the determination in operation 1250 that the corresponding weight data is not the last weight data, the IMC processor may increase the value of i by “1” to retrieve the next weight data, and perform a shift operation on the operation result stored in the 2D shift accumulator, in operation 1260.

In response to the determination in operation 1250 that the corresponding weight data is the last weight data, the IMC processor may output the result of accumulation stored in buffers of the 2D shift accumulator and initialize the buffers of the 2D shift accumulator, in operation 1270.

For example, it may be assumed that the length of an input channel is equal to the length of a column of the SRAM IMC macro and a 3×3 convolution operation is to be performed. The IMC processor may divide weight data of a weight map into nine vectors corresponding to the column size of the SRAM IMC macro, and perform an operation with the weight data i over nine loops.

The example of FIG. 12 shows a case of the number of weight maps (or kernels) being 1. If the number of weight maps is K, the IMC processor may iteratively perform the process described above K times again. Even if the number of weight maps is K, the IMC processor may perform the operation described above with the same input data stored in the memory array by reusing the input.

The process described above with reference to FIG. 12 may also apply to a depth-wise convolution, for example. Depending on an example, if there are a small number of input channels, the IMC processor may adjust the number of columns for addition through an adder (e.g., an adder tree), thereby compensating for a reduction in computational efficiency.

The computing apparatuses, the electronic devices, the processors, the memories, the displays, the information output system and hardware, the storage devices, and other apparatuses, devices, units, modules, and components described herein with respect to FIGS. 1-12 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-12 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An in-memory computing (IMC) processor comprising:
IMC macros;
a static random access memory (SRAM) IMC device comprising the IMC macros, and configured to perform a multiply and accumulate (MAC) operation between input data and first weight data of a first weight map applied to a first of the IMC macros in a first direction in which an input feature map comprising the input data is written to the first IMC macro; and
a two-dimensional (2D) shift accumulator configured to perform a shift operation on partial sums corresponding to respective MAC operation results of the IMC macros and accumulate a result of the shift operation.

2. The IMC processor of claim 1, wherein
an output end of the first IMC macro is connected to an input end of a second of the IMC macros, and
the SRAM IMC device is configured to:
write data of an output feature map of the first IMC macro to a second memory array of the second IMC macro in the first direction as the input data in parallel, and
perform, in response to second weight data of a second weight map being applied to the second IMC macro, a MAC operation between the data written to the second memory array and the second weight data in the first direction.

3. The IMC processor of claim 1, wherein
the IMC macros are configured to share the 2D shift accumulator.

4. The IMC processor of claim 1, wherein
the 2D shift accumulator comprises a buffer,
wherein the buffer comprises:
a first region for storing or accumulating a MAC operation result corresponding to the first IMC macro; and
a second region for preventing data loss due to the shift operation, and
the size of the first region and the size of the second region are determined based on a size of the first IMC macro.

5. The IMC processor of claim 1, wherein
the 2D shift accumulator is configured to perform an accumulate operation on the partial sums by performing the shift operation on the respective MAC operation results of the IMC macros in at least one direction of up, down, left, and right directions.

6. The IMC processor of claim 1, wherein
the input feature map comprises 2D input data corresponding to word lines and bit lines of a first memory array included in the first IMC macro.

7. The IMC processor of claim 1, wherein
the MAC operation comprises a linear operation or a convolution operation.

8. The IMC processor of claim 1, further comprising:
an input streamer configured to delay applying a weight map corresponding to each of the IMC macros by a unit cycle and to apply the delayed weight map to the corresponding IMC macro.

9. The IMC processor of claim 8, wherein
the input streamer is configured to read, from memory devices, weight data of weight maps corresponding to one or more IMC macros that are operable at the same time among the IMC macros, and apply the read weight data to the corresponding IMC macro at a point in time delayed by the unit cycle, for each of the one or more IMC macros.

10. The IMC processor of claim 1, wherein
each of the IMC macros comprises:
a memory array comprising bit cells, wherein bit cells connected to the same bit lines are configured to receive the same 1-bit weight data, and wherein each of the bit cells is configured to perform an AND operation between input data stored in the corresponding bit cell and weight data of a weight map corresponding to each of the IMC macros; and
a digital operator configured to accumulate a result of the AND operations of the respective bit cells.

11. The IMC processor of claim 10, wherein
the digital operator comprises:
an adder configured to perform an add operation on the result of the AND operation; and
a shift accumulator configured to sequentially accumulate a result of the add operation through a shift operation.

12. The IMC processor of claim 10, wherein
the memory array comprises:
word lines;
bit lines intersecting with the word lines; and
the bit cells disposed at intersecting points between the word lines and the bit lines,
wherein each of the bit cells is configured to store the input data.

13. The IMC processor of claim 1, wherein
the IMC processor is integrated into at least one device selected from the group consisting of a mobile device, a mobile computing device, a mobile phone, a smart phone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, and a medical device.

14. A static random access memory (SRAM) in-memory computing (IMC) macro device, comprising:
IMC macros, wherein the SRAM IMC macro device is configured to perform a multiply and accumulate (MAC) operation between input data and first weight data of a first weight map applied to a first of the IMC macros in a first direction in which an input feature map comprising the input data is written to the first IMC macro.

15. The SRAM IMC macro device of claim 14, wherein
an output of the first IMC macro is connected to an input a second of the IMC macros, and wherein the SRAM IMC device is further configured to:
write data, of an output feature map of the first IMC macro, to a second memory array of the second IMC macro, in the first direction as the input data in parallel, and
perform, in response to second weight data of a second weight map being applied to the second IMC macro, a MAC operation between the data written to the second memory array and the second weight data in the first direction.

16. An operating method of an in-memory computing (IMC) processor comprising IMC macros, the operating method comprising:
writing input data of an input feature map to a first of the IMC macros in a first direction;
performing a multiply and accumulate (MAC) operation between the input data and weight data of a weight map corresponding to the first IMC macro by reading the weight data and applying the weight data to the first IMC macro in the first direction;
accumulating a result of the MAC operation in a two-dimensional (2D) shift accumulator; and
outputting a result of the accumulating according to whether the weight data is last data of the weight map.

17. The operating method of claim 16, wherein
the performing of the MAC operation comprises delaying applying a weight map corresponding to each of the IMC macros by a unit cycle and applying the delayed weight map to the corresponding IMC macro.

18. The operating method of claim 17, wherein
the applying to the corresponding IMC macro comprises:
reading weights corresponding to one or more IMC macros that are operable at the same time among the IMC macros; and
applying the read weight data to a memory array of the corresponding IMC macro in the first direction at a point in time delayed by the unit cycle, for each of the one or more IMC macros.

19. The operating method of claim 16, wherein
the performing of the MAC operation comprises iteratively reading the weight data and applying the read weight data to a memory array of the first IMC macro in the first direction until a last bit of a column channel of the weight map stored in a memory device is reached.

20. The operating method of claim 16, wherein
the outputting of the result of the accumulating comprises:
reading next weight data of the weight data from the weight map and applying the next weight data to the first IMC macro, in response to the weight data not being the last data of the weight map; and
shifting the result of the operation in the 2D shift accumulator.
